(19) United States
(12) Patent Application Publication
(10) Pub. No.: US 2008/0072954 A1
(43) Pub. Date: Mar. 27, 2008

(54) METHOD OF SEALING SOLAR CELLS

(75) Inventors: Yu-Yang Chang, Tainan (TW); Wei-Yi Lin, Yunlin (TW); Ming-Chun Hsiao, Hsinchu (TW); Cheng-Chung Lee, Taitung County (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/672,880

(22) Filed: Feb. 8, 2007

(30) Foreign Application Priority Data
Sep. 27, 2006 (TW) TW95135735

(51) Int. Cl. H02N 6/00; H01L 31/00

(52) U.S. Cl. 136/251; 136/263

(57) ABSTRACT

A method of sealing a solar cell. A first substrate is provided. A semiconductor layer is coated on the first substrate. A second substrate is provided. A metal layer is coated on the second substrate. The first and second substrates are assembled to form a space therebetween, wherein the semiconductor layer is opposite to the metal layer. The air is removed from the space to achieve a vacuum such that a dye solution is refilled thereto. An electrolyte is filled in the space. The space is sealed.

### BACKGROUND OF THE INVENTION

1. Field of the Invention

The invention relates to a method of sealing a semiconductor or display device, and in particular to a method of sealing a solar cell.

2. Description of the Related Art

Dye-sensitized solar cells (DSSC) absorb photoenergy to produce electron flow utilizing organic dyes and absorbing and collecting electrons using a composite laminate structure. Photoconversion efficiency of solar cell devices depends on dye coating quality because electron-hole pair numbers and dye amounts on titanium dioxide (TiO₂) are proportionate.

In FIG. 1, a conventional fabrication method of a dye-sensitized solar cell is disclosed. A dye-sensitized solar cell 10 comprises an upper conductive glass substrate 12 and a lower conductive glass substrate 14. A titanium dioxide solution is coated on the upper conductive glass substrate 12 to form a titanium dioxide layer 16. After heating, the titanium dioxide layer 16 becomes a spongy and porous film with a larger surface area (about 10 μm thickness). Next, a dye solution containing ruthenium, anthocyanidins, or chlorophyll is coated on the titanium dioxide layer 16 to form a dye layer 18 as a light absorber. An electrolyte 20 containing iodine ions is then dropped on the dye layer 18.

A metal catalyst layer 22, such as platinum (Pt), is coated on the lower conductive glass substrate 14. Finally, the upper conductive glass substrate 12 and the lower conductive glass substrate 14 are assembled to form a solar cell device 10. Electrons are driven by exposure of the titanium dioxide layer 16.

The inner surface of the titanium dioxide layer, however, is often occupied by moisture such that dye coating area is reduced, deteriorating photoconversion efficiency and device lifetime.

Additionally, current organic sealing materials are easily damaged after chronic light exposure, resulting in electrolyte leakage. Replacement by other sealing materials is feasible. Inorganic materials, such as glass, are preferable due to the same material as the upper and lower glass substrates.

### BRIEF SUMMARY OF THE INVENTION

The invention provides a method of sealing a solar cell, in which a first substrate is provided. A semiconductor layer is coated on the first substrate. A second substrate is provided. A metal layer is coated on the second substrate. The first and second substrates are assembled to form a space therebetween, wherein the semiconductor layer is opposite to the metal layer. The air is removed from the space to achieve a vacuum such that a dye solution is refilled thereto. An electrolyte is filled in the space. The space is sealed.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 is a cross section of a conventional method of fabricating a dye-sensitized solar cell.

FIGS. 2A˜2H are cross sections of a method of sealing a dye-sensitized solar cell of the invention.

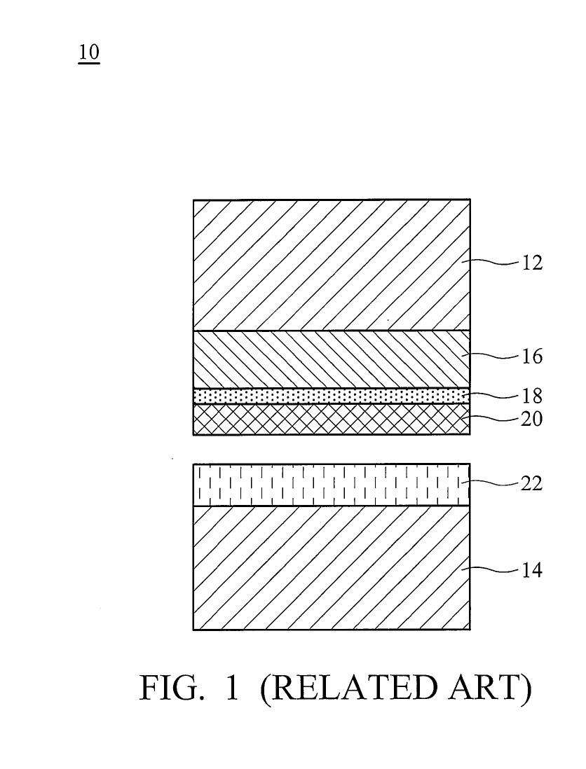

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides a method of sealing a solar cell, in which a first substrate is provided. A semiconductor layer is coated on the first substrate. A second substrate is provided. A metal layer is coated on the second substrate. The first and second substrates are assembled to form a space therebetween, wherein the semiconductor layer is opposite to the metal layer. The air is removed from the space to achieve a vacuum such that a dye solution is refilled thereto. An electrolyte is filled in the space. The space is sealed.

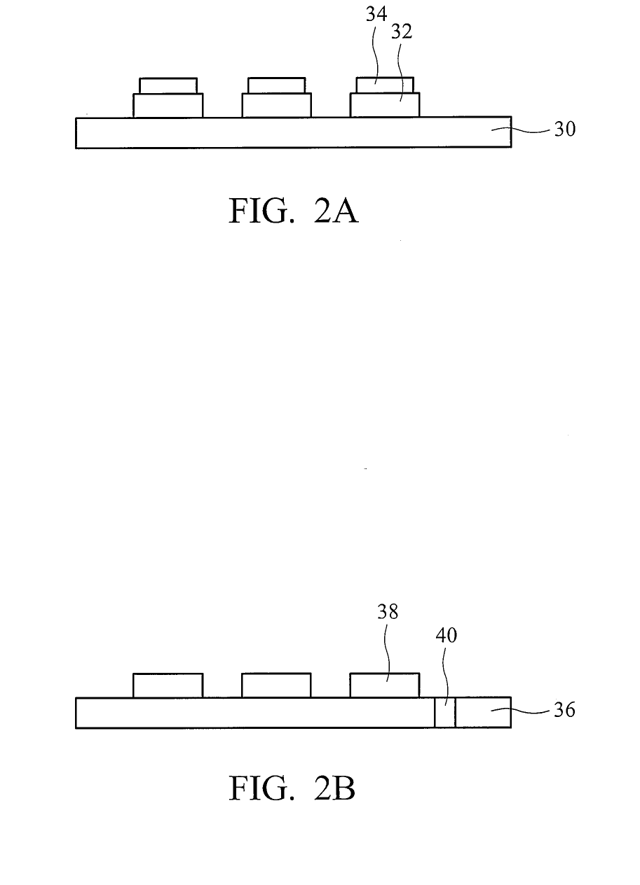

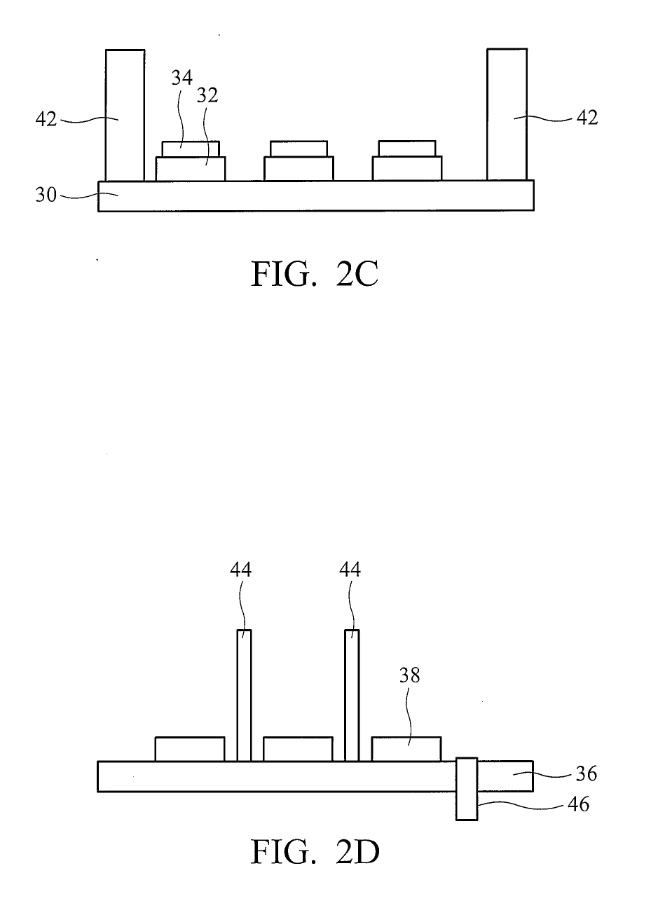

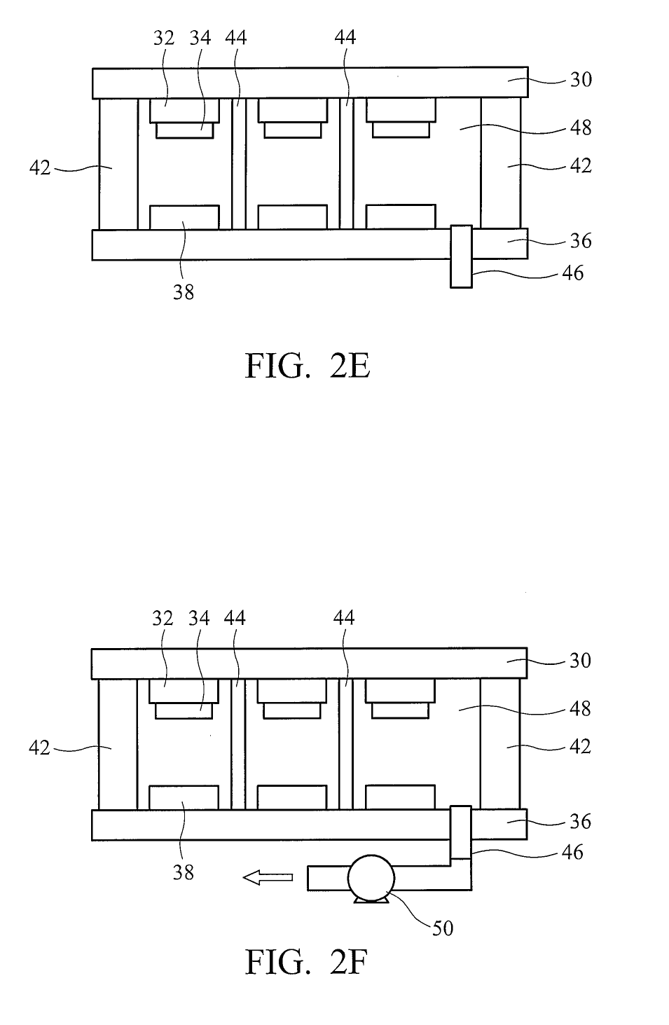

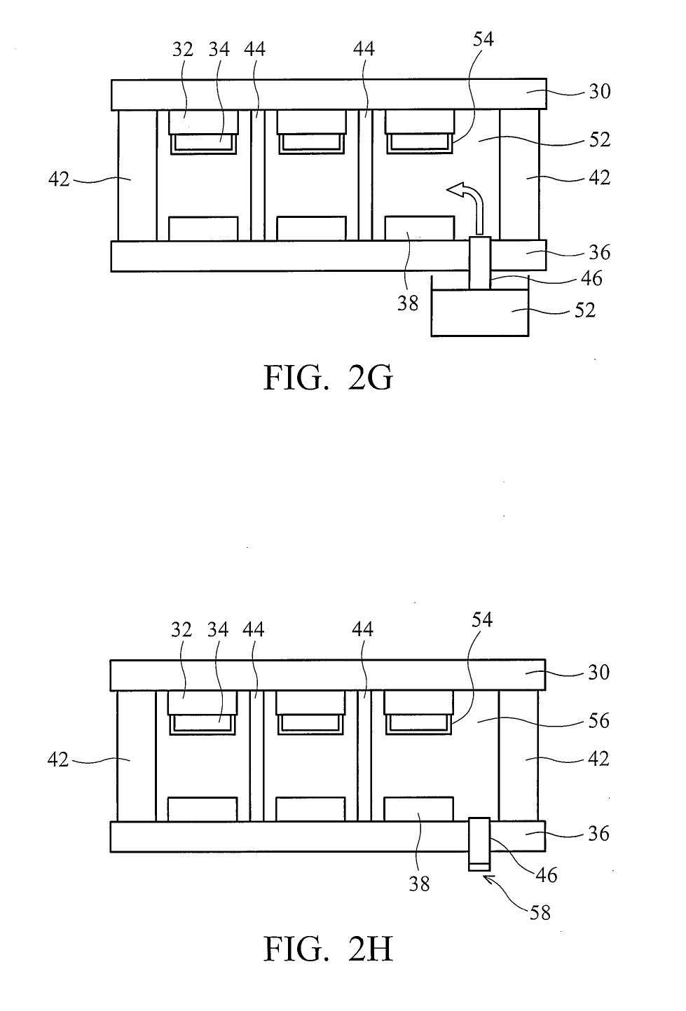

A method of sealing a solar cell of the invention is disclosed in FIGS. 2A˜2H.

Referring to FIG. 2A, a first substrate 30, such as a glass substrate, is provided. Next, a conductive layer 32 is formed on the first substrate 30. The conductive layer 32 may comprise indium tin oxide (ITO) or aluminum zinc oxide (AZO). A semiconductor layer 34, such as a titanium dioxide (TiO₂) layer, is then coated on the conductive layer 32.

Referring to FIG. 2B, a second substrate 36, such as a glass substrate, is provided. Next, a metal layer 38 is coated on the second substrate 36. The metal layer 38 may comprise palladium (Pd) or platinum (Pt). An opening 40 for subsequent air exhaust is then formed through the terminal of the second substrate 36. The opening 40 is not limited thereto and may be formed through the terminal of the first substrate 30.

Referring to FIG. 2C, a plurality of side frames 42 are formed on the terminal of the first substrate 30 by such as screen printing or dispersion. The side frames 42 may comprise glass gel.

Referring to FIG. 2D, a plurality of rib structures 44 for cell height control are formed on the exposed second substrate 36 by such as screen printing or sintering. The rib structures 44 may comprise glass gel. Next, an exhaust tube 46 is disposed in the opening 40. The exhaust tube 46 may comprise glass, metal or alloy. The foregoing cell fabrication may be modified, for example, by the side frames 42 being formed on the second substrate 36 and the rib structures 44 formed on the first substrate 30.

Referring to FIG. 2E, the first substrate 30 and the second substrate 36 are assembled such that the semiconductor layer 34 is opposite to the metal layer 38. The height of the cell is controlled by the rib structures 44. A space 48 is formed between the first substrate 30 and the second substrate 36 by installation of the side frames 42.

Referring to FIG. 2F, the air is removed from the space 48 through the exhaust tube 46 connecting with an air-exhausting apparatus, leaving a vacuum pressure of about 10⁻²˜10⁻⁶ torr. The cell is heated at a temperature of about 100˜350° C. to remove moisture absorbed by the semiconductor layer 34, simultaneously.

After air exhaust, a pressure drop between the space 48 and environment is formed such that a dye solution 52 is refilled to the space 48 and absorbed by the semiconductor layer 34 to form a dye layer 54 thereon, as shown in FIG. 2G. The dye solution 52 may comprise ruthenium, anthocyanidins, or chlorophyll.

In an embodiment, moisture absorbed by the nano-porous titanium dioxide (TiO₂) layer is easily removed by the vacuum sealing technology. Thus, dye coating area is enlarged, improving photoelectrical efficiency. Also, the dye solution is directly refilled to the cell by pressure drop, simplifying the fabrication. Additionally, after chronic light exposure, the glass-gel sealing material (side frame and rib structure) remains without damage.

After removing dye solution 52 not absorbed by the semiconductor layer 34, an electrolyte 56 is filled in the space 48. The electrolyte may comprise iodine ion. Finally, the cell is sealed, for example, the exhaust tube 46 is sealed 58 at room temperature, as shown in FIG. 2H, or after removing the exhaust tube 46, the leaving opening is sealed.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of sealing a solar cell, comprising:
providing a first substrate;
coating a semiconductor layer on the first substrate;
providing a second substrate;
coating a metal layer on the second substrate;
assembling the first and second substrates to form a space therebetween, wherein the semiconductor layer is opposite to the metal layer;
removing the air from the space to achieve a vacuum such that a dye solution is refilled thereto;
filling an electrolyte in the space; and
sealing the space.

2. The method of sealing the solar cell as claimed in claim 1, wherein the first and second substrates are glass substrates.

3. The method of sealing the solar cell as claimed in claim 1, wherein the semiconductor layer is a titanium dioxide (TiO₂) layer.

4. The method of sealing the solar cell as claimed in claim 1, further comprising forming a conductive layer between the semiconductor layer and the first substrate.

5. The method of sealing the solar cell as claimed in claim 4, wherein the conductive layer comprises indium tin oxide (ITO) or aluminum zinc oxide (AZO).

6. The method of sealing the solar cell as claimed in claim 1, wherein the metal layer comprises palladium (Pd) or platinum (Pt).

7. The method of sealing the solar cell as claimed in claim 1, further comprising forming an opening through the first substrate or the second substrate to connect the space with environment.

8. The method of sealing the solar cell as claimed in claim 7, further comprising disposing an exhaust tube in the opening connecting with an air-exhausting apparatus to remove the air from the space.

9. The method of sealing the solar cell as claimed in claim 8, wherein the exhaust tube comprises glass, metal, or alloy.

10. The method of sealing the solar cell as claimed in claim 1, further comprising heating the first and second substrates when the air is removed from the space.

11. The method of sealing the solar cell as claimed in claim 10, wherein the heating temperature is about 100˜350° C.

12. The method of sealing the solar cell as claimed in claim 1, wherein the vacuum pressure is about 10⁻²˜10⁻⁶ torr.

13. The method of sealing the solar cell as claimed in claim 1, wherein the dye solution is refilled into the space by a pressure drop between the space and environment.

14. The method of sealing the solar cell as claimed in claim 1, wherein the dye solution comprises ruthenium, anthocyanidins, or chlorophyll.

15. The method of sealing the solar cell as claimed in claim 1, further comprising removing dye solution not absorbed by the semiconductor layer from the space before the electrolyte is filled therein.

16. The method of sealing the solar cell as claimed in claim 1, wherein the electrolyte comprises iodine ion.
